(19) United States
(12) Patent Application Publication
(10) Pub. No.: US 2018/0223048 A1
(43) Pub. Date: Aug. 9, 2018

(54) RESIN COMPOSITION, METHOD FOR MAKING RESIN COMPOSITION AND FILM FOR CIRCUIT BOARD, AND CIRCUIT BOARD

(71) Applicant: Zhen Ding Technology Co., Ltd., Tayuan (TW)

(72) Inventors: MAO-FENG HSU, Taoyuan (TW); SHOU-JUI HSIANG, Taoyuan (TW); SZU-HSIANG SU, Taoyuan (TW); YU-WEN KAO, Taoyuan (TW); CHIA-YIN TENG, Taoyuan (TW); MING-JAAN HO, New Taipei (TW); YAO-YI CHENG, Taoyuan (TW); HSIN-MIN HSIAO, Taoyuan (TW)

(21) Appl. No.: 15/686,232

(22) Filed: Aug. 25, 2017

(30) Foreign Application Priority Data
Feb. 8, 2017 (CN) 201710068734.7

(51) Int. Cl. C08G 81/02; C09D 179/08; C03C 17/32; H05K 1/03; H05K 3/22; H05K 1/02

(52) U.S. Cl. CPC C08G 81/024; C09D 179/08; C03C 17/32; H05K 2201/0158; H05K 3/22; H05K 1/0393; H05K 1/024; H05K 1/0326

(57) ABSTRACT

A resin composition having lower dielectric constant Dₖ, lower dielectric loss D_{f}, lower water absorption, higher surface impedance, and higher glass transition temperature includes resins. The resins have a chemical structure selected from a group consisting of

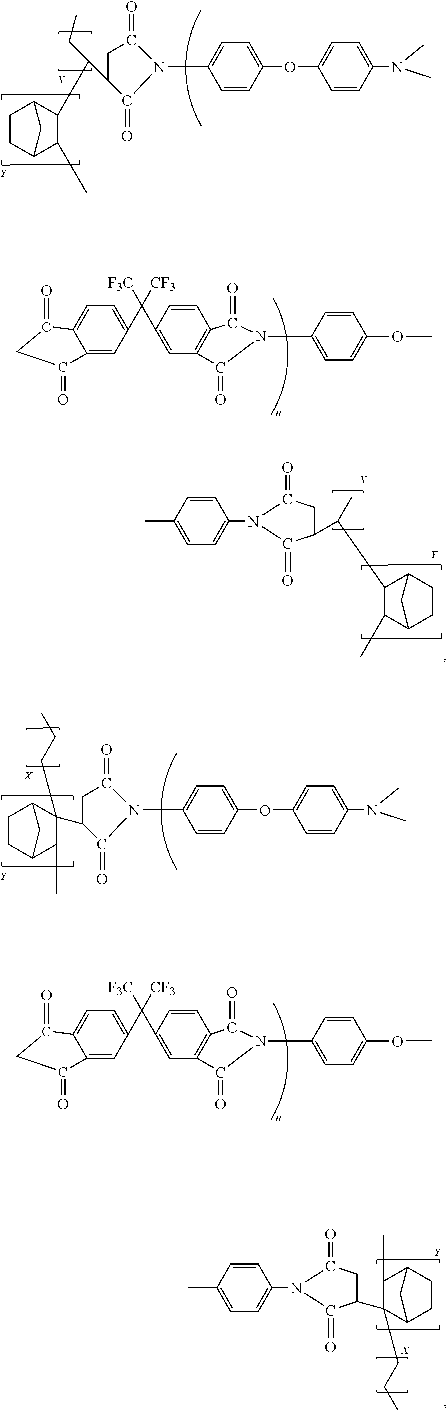

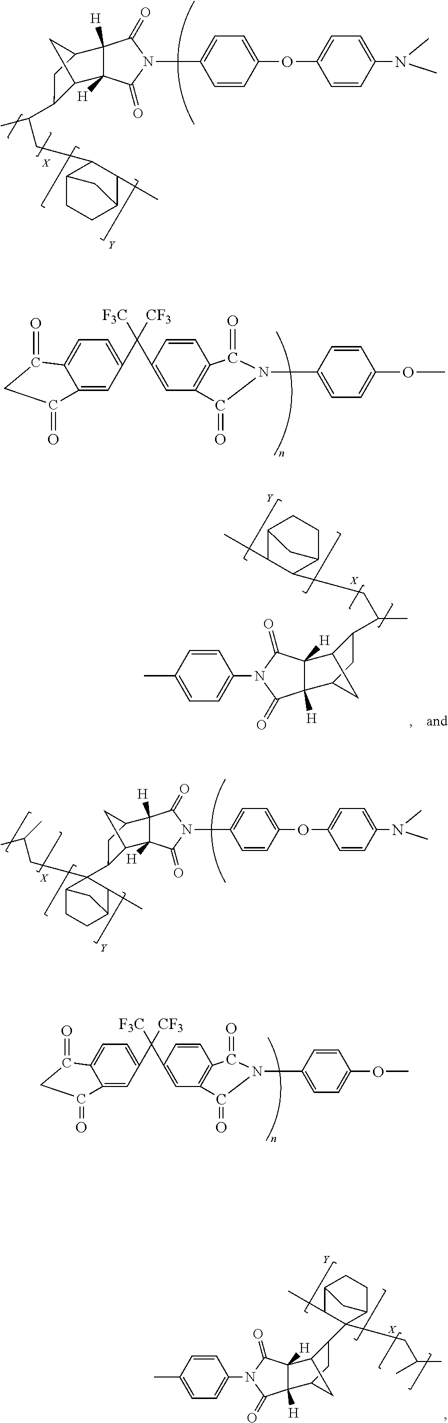

or any combination thereof.

### FIELD

The subject matter herein generally relates to a resin composition, a method for making the resin composition, a method for making a film for a circuit board, and a circuit board having the film.

### BACKGROUND

Flexible circuit boards usually include polyimide films. Such a polyimide film is formed by diamine compounds and anhydride compounds, and has a high dielectric constant Dₖ (greater than 3.2) and a high dielectric loss D_{f}. Thus, the flexible circuit board cannot provide an impedance match for high frequency signals to be transmitted thereto.

### BRIEF DESCRIPTION OF THE DRAWINGS

Implementations of the present technology will now be described, by way of example only, with reference to the attached figures.

FIG. 1 is a flowchart of an exemplary embodiment of a method for making a resin composition.

FIG. 2 is a sub-flowchart of an exemplary embodiment of a method for making modified cyclic olefin copolymers in the method of FIG. 1.

FIG. 3 is a sub-flowchart of an exemplary embodiment of a method for making polyamic acid solution in the method of FIG. 1.

FIG. 4 is a flowchart of an exemplary embodiment of a method for making a film.

FIG. 5 is a diagrammatic view of an exemplary embodiment of a circuit board.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

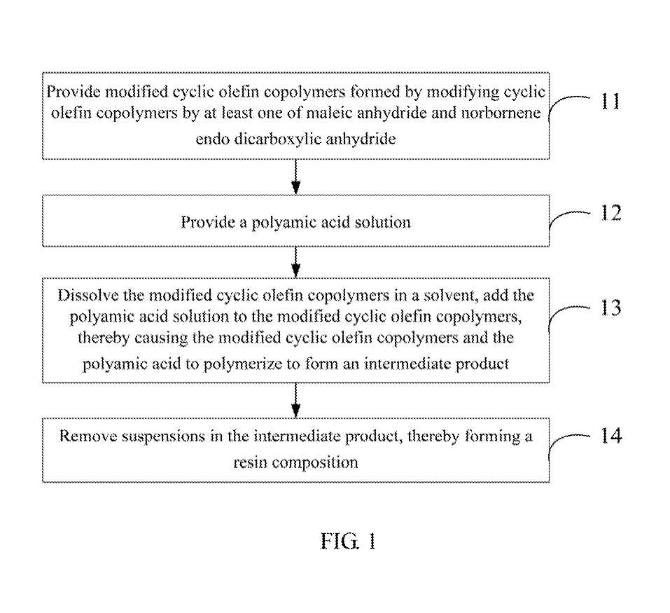

FIG. 1 illustrates a flowchart of a method for making a resin composition in accordance with an exemplary embodiment. The exemplary method is provided by way of example, as there are a variety of ways to carry out the method. Each block shown in the figure represents one or more processes, methods, or subroutines, carried out in the exemplary method. Furthermore, the illustrated order of blocks is by example only, and the order of the blocks can change. Additional blocks may be added, or fewer blocks may be utilized, without departing from this disclosure. The exemplary method can begin at block 11.

At block 11, modified cyclic olefin copolymers are provided which are formed by modifying cyclic olefin copolymers by at least one of maleic anhydride and norbornene endo dicarboxylic anhydride. The maleic anhydride has a chemical structure of

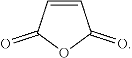

The norbornene endo dicarboxylic anhydride has a chemical structure of

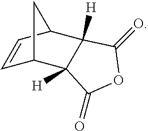 [SMILES: O=C1OC(=O)[C@H]2C3C=CC(C3)[C@@H]12]

The modified cyclic olefin copolymers formed by the maleic anhydride have at least one chemical structure of

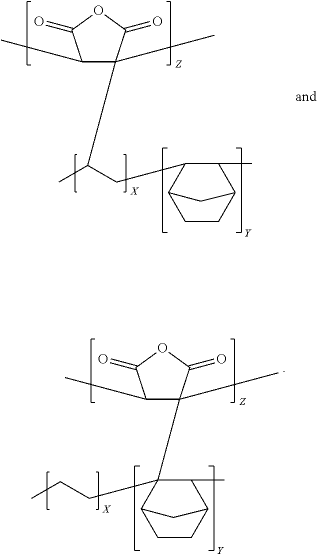

The modified cyclic olefin copolymers formed by the norbornene endo dicarboxylic anhydride have at least one chemical structure of

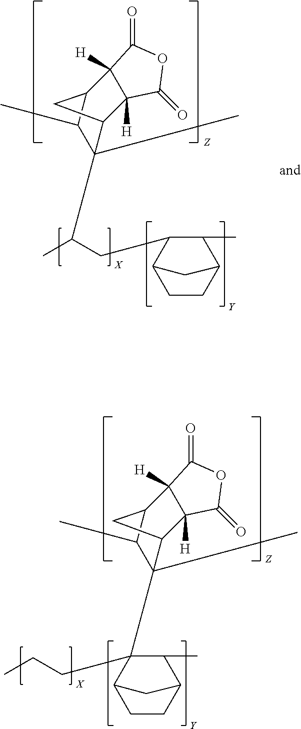

At blocked 12, a polyamic acid solution is provided. The polyamic acid solution comprises polyamic acid having a chemical structure of

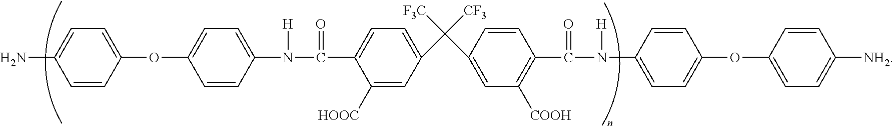

At block 13, the modified cyclic olefin copolymers are dissolved in a solvent. The polyamic acid solution is added to the modified cyclic olefin copolymers, thereby causing the modified cyclic olefin copolymers and the polyamic acid to polymerize to form an intermediate product. In at least one exemplary embodiment, the modified cyclic olefin copolymers and the polyamic acid solution are in a ratio of about 1:9 to about 2:3 by weight. The modified cyclic olefin copolymers and the polyamic acid polymerize at a normal temperature and for about 24 hours. The solvent can be methylbenzene. The amount of the methylbenzene can be varied, ensuring that the modified cyclic olefin copolymers can be completely dissolved therein.

At block 14, suspensions in the intermediate product are removed, thereby forming the resin composition.

In at least one exemplary embodiment, the resin composition comprises resins having a chemical structure selected from a group consisting of

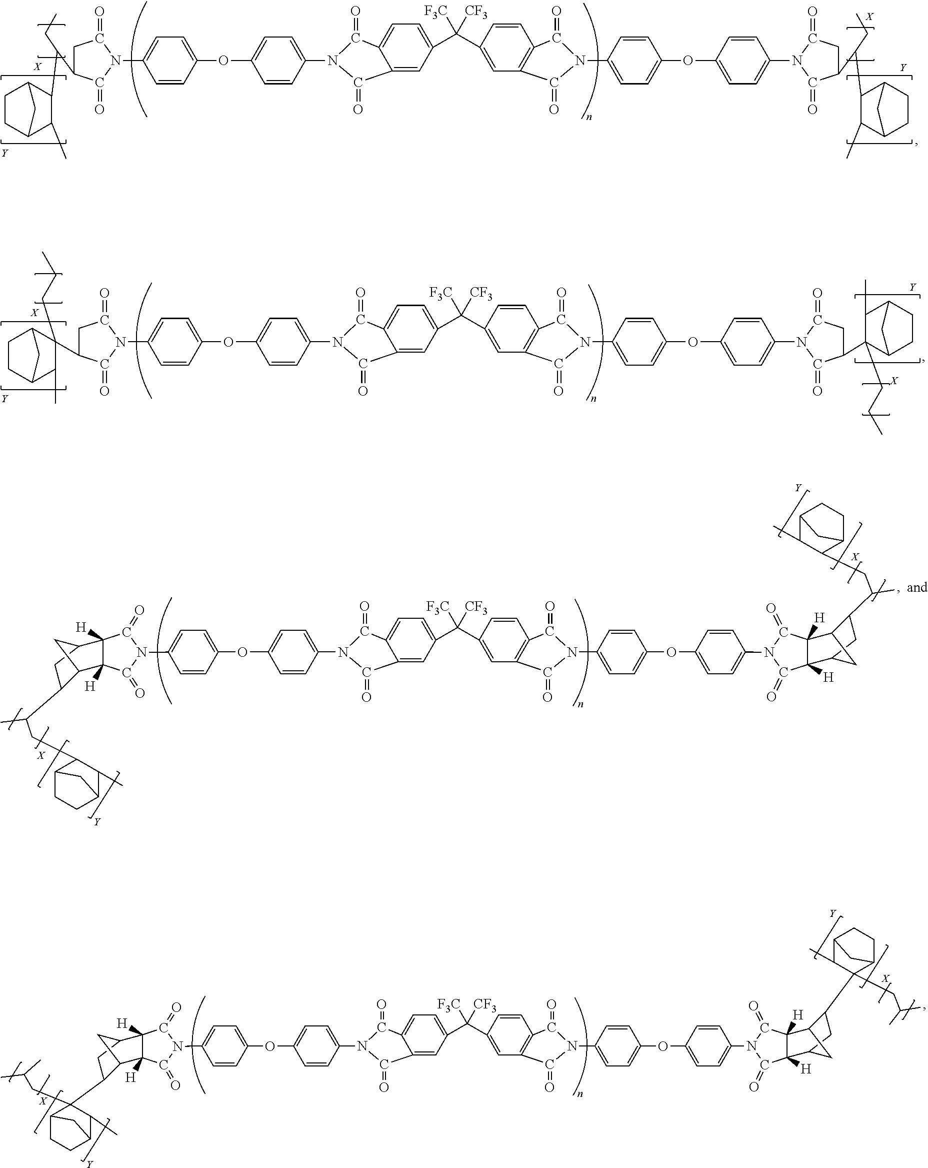

or any combination thereof.

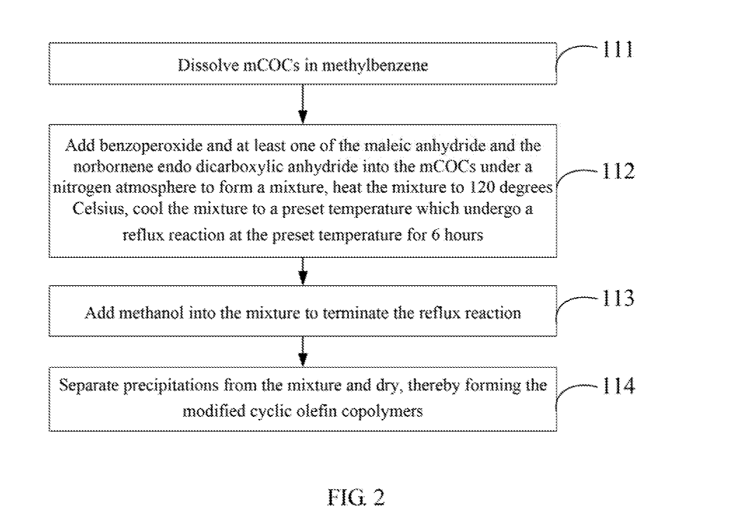

FIG. 2 illustrates a flowchart of a method for making the modified cyclic olefin copolymers in accordance with an exemplary embodiment. The exemplary method is provided by way of example, as there are a variety of ways to carry out the method. Each block shown in the figure represents one or more processes, methods, or subroutines, carried out in the exemplary method. Furthermore, the illustrated order of blocks is by example only, and the order of the blocks can change. Additional blocks may be added, or fewer blocks may be utilized, without departing from this disclosure. The exemplary method can begin at block 111.

At block 111, metallocene cyclic olefin copolymers (mCOCs) and methylbenzene are mixed, stirred, and heated to cause the metallocene cyclic olefin copolymers to be dissolved in the methylbenzene. The metallocene cyclic olefin copolymers have a chemical structure of

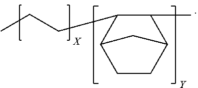

At block 112, benzoperoxide and at least one of the maleic anhydride and the norbornene endo dicarboxylic anhydride are added into the metallocene cyclic olefin copolymers under a nitrogen atmosphere to form a mixture. The mixture is heated to about 120 degrees Celsius, cooled to a preset temperature, and undergoes a reflux reaction at the preset temperature for about 6 hours.

At block 113, a methanol is added into the mixture after the reflux reaction. Since the methanol can dilute the mixture, the methanol can terminate the reflux reaction.

At block 114, precipitations are separated from the mixture and dried, thereby forming the modified cyclic olefin copolymers. In at least one exemplary embodiment, the at least one of the maleic anhydride and the norbornene endo dicarboxylic anhydride is grafted to the cyclic olefin copolymers to form the modified cyclic olefin copolymers. The grafted maleic anhydride and/or the norbornene endo dicarboxylic anhydride is in a range of about 3% with respect to the modified cyclic olefin copolymers by weight. That is, a grafting ratio of the at least one of the maleic anhydride and the norbornene endo dicarboxylic anhydride is of about 3%.

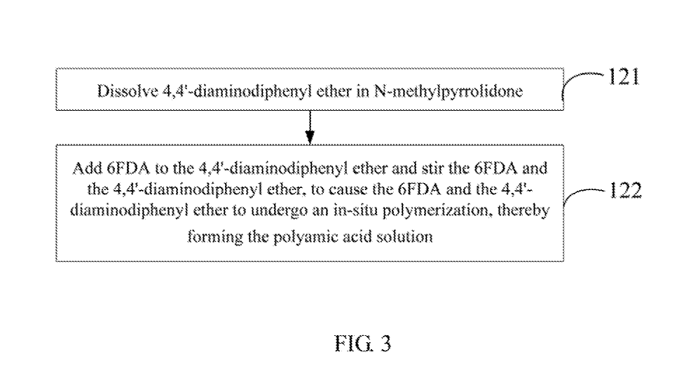

FIG. 3 illustrates a flowchart of a method for making the polyamic acid solution in accordance with an exemplary embodiment. The exemplary method is provided by way of example, as there are a variety of ways to carry out the method. Each block shown in the figure represents one or more processes, methods, or subroutines, carried out in the exemplary method. Furthermore, the illustrated order of blocks is by example only, and the order of the blocks can change. Additional blocks may be added, or fewer blocks may be utilized, without departing from this disclosure. The exemplary method can begin at block 121.

At block 121, 4,4′-diaminodiphenyl ether is dissolved in N-methylpyrrolidone.

At block 122, 4,4′-(hexafluoroisopropylidene) diphthalic anhydride (6FDA) is added to the 4,4′-diaminodiphenyl ether, and is stirred to cause the 4,4′-(hexafluoroisopropylidene) diphthalic anhydride and the 4,4′-diaminodiphenyl ether to undergo an in-situ polymerization, thereby forming the polyamic acid solution. In at least one exemplary embodiment, the 4,4′-(hexafluoroisopropylidene) diphthalic anhydride and the 4,4′-diaminodiphenyl ether undergo the in-situ polymerization for about 24 hours.

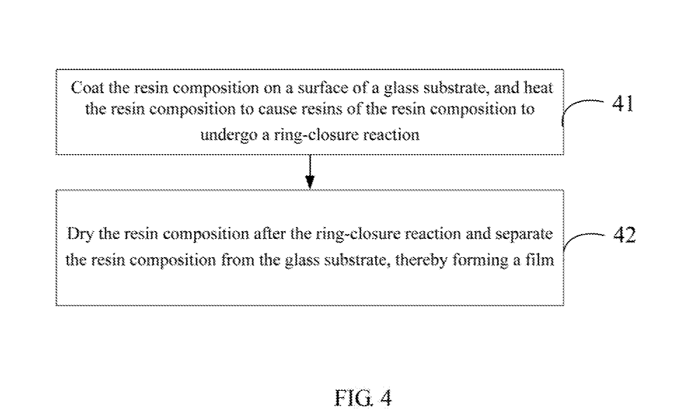

FIG. 4 illustrates a flowchart of a method for making a film 20 (shown in FIG. 4) using the resin composition in accordance with an exemplary embodiment. The exemplary method is provided by way of example, as there are a variety of ways to carry out the method. Each block shown in the figure represents one or more processes, methods, or subroutines, carried out in the exemplary method. Furthermore, the illustrated order of blocks is by example only, and the order of the blocks can change. Additional blocks may be added, or fewer blocks may be utilized, without departing from this disclosure. The exemplary method can begin at block 41.

At block 41, the resin composition is coated on a surface of a glass substrate, and is heated to cause the resins of the resin composition to undergo a ring-closure reaction. In at least one exemplary embodiment, the resin composition is placed in a furnace and heated from normal temperature to 300 degrees Celsius via five heating processes. The first heating process is heating the resin composition from normal temperature to 100 degrees Celsius and remaining the resin composition at 100 degrees Celsius for one hour. The second heating process is heating the resin composition from 100 degrees Celsius to 150 degrees Celsius and remaining the resin composition at 150 degrees Celsius for one hour. The third heating process is heating the resin composition from 150 degrees Celsius to 200 degrees Celsius and remaining the resin composition at 200 degrees Celsius for one hour. The fourth heating process is heating the resin composition from 200 degrees Celsius to 250 degrees Celsius and remaining the resin composition at 250 degrees Celsius for one hour. The fifth heating process is heating the resin composition from 250 degrees Celsius to 300 degrees Celsius and remaining the resin composition at 300 degrees Celsius for two hours.

At block 42, the resin composition after the ring-closure reaction is dried and separated from the glass substrate, thereby forming the film 20.

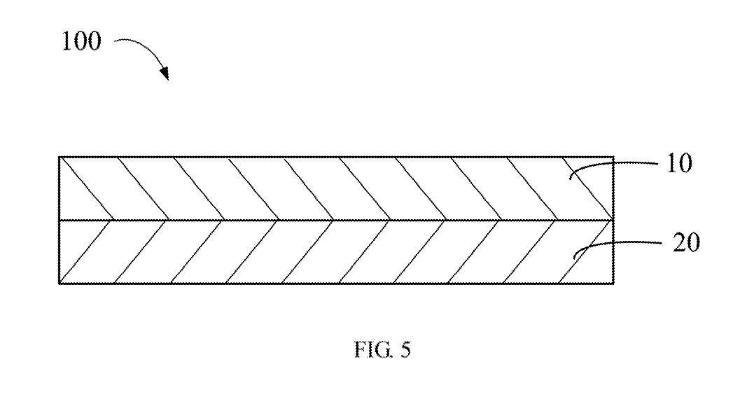

FIG. 5 illustrates an exemplary embodiment of a circuit board 100 comprising at least one substrate 10 and a film 20 formed on at least one surface of each substrate 10. The film 20 is formed by heating the resin composition to cause the resins of the resin composition to undergo a ring-closure reaction.

In the resin composition, the modified cyclic olefin copolymers can decrease the dielectric constant Dₖ and the dielectric loss D_{f} of the resins. Furthermore, the resin composition can form a cross-linking structure when the resin composition is heated to form the film, which can increase the cross-linking density of the film 20 so that the film 20 can have an improved heat resistance, for soldering. Thus the film 20 can have an improved thermal resistance. Moreover, the film 20 has low water absorption, that is, the film 20 has an improved hydrophobic property.

### Example 1

mCOCs of 1.5 g and methylbenzene of 20 mL were mixed in a first container. The first container was connected to a condenser pipe, placed and heated in an oil bath, and stirred by an electromagnetic stirring device, to cause the mCOCs to be dissolved in the methylbenzene. Benzoperoxide of 0.087 g and maleic anhydride of 0.351 g were added into the first container under a nitrogen atmosphere, heated to 120 degrees Celsius, and cooled to 20 degrees Celsius by a cooling water circulation device, to initiate a reflux reaction for 6 hours. Methanol of 100 mL was added into the first container to terminate the reflux reaction. Precipitations were separated from the first container, washed until the water became transparent, and dried at 120 degrees Celsius in a vacuum drying oven for 2 hours to form the modified cyclic olefin copolymers (chemical structure:

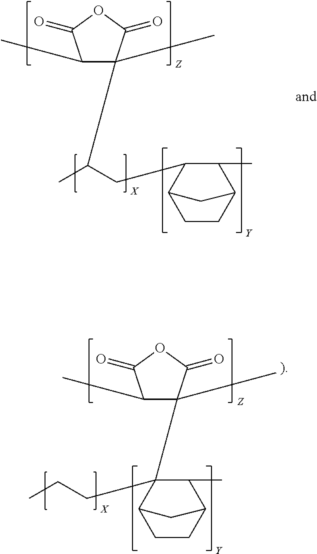

A grafting ratio of the maleic anhydride is of 3%.

4,4′-diaminodiphenyl ether of 0.371 g and N-methylpyrrolidone of 8.7 mL were added into a second container and stirred to cause the 4,4′-diaminodiphenyl ether to be dissolved in the N-methylpyrrolidone. 6FDA of 0.798 g was added to the second container and stirred to begin an in-situ polymerization for 24 hours, thereby forming a polyamic acid solution.

The modified cyclic olefin copolymers of 0.44 g and methylbenzene of 9.43 mL were added into a third container and stirred by an electromagnetic stirring device to cause the modified cyclic olefin copolymers to be dissolved in the methylbenzene. The polyamic acid solution was added to the modified cyclic olefin copolymers and polymerized with the modified cyclic olefin copolymers for 24 hours to form the resin composition. The modified cyclic olefin copolymers and the polyamic acid solution were in a ratio of 27:73 by weight. The resin composition comprised resins having chemical structures of

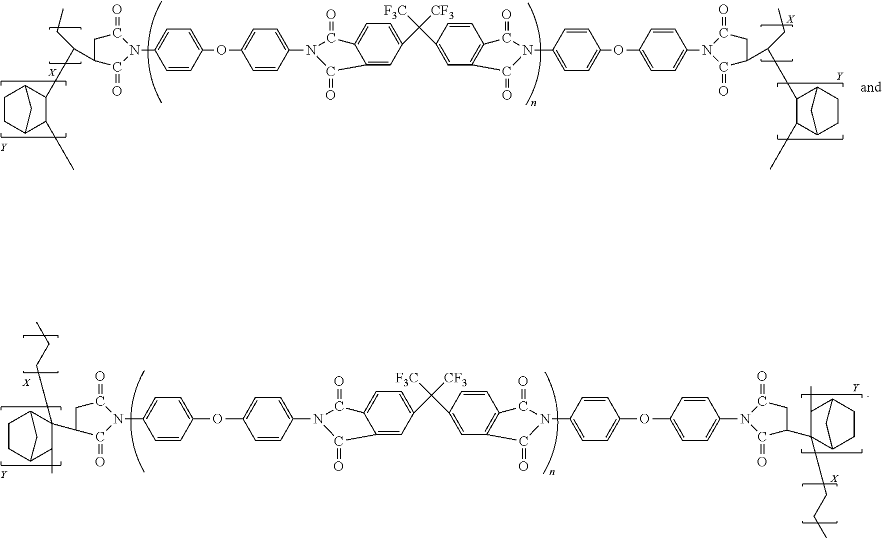

The resin composition was coated on a surface of a glass substrate, heated in a furnace from normal temperature to 100 degrees Celsius and remained at 100 degrees Celsius for one hour, then from 100 degrees Celsius to 150 degrees Celsius and remained at 150 degrees Celsius for one hour, then from 150 degrees Celsius to 200 degrees Celsius and remained at 200 degrees Celsius for one hour, then from 200 degrees Celsius to 250 degrees Celsius and remained for one hour, and finally from 250 degrees Celsius to 300 degrees Celsius and remained at 300 degrees Celsius for two hours. On separation from the glass substrate, the film 20 is formed.

### Example 2

Modified cyclic olefin copolymers (chemical structure:

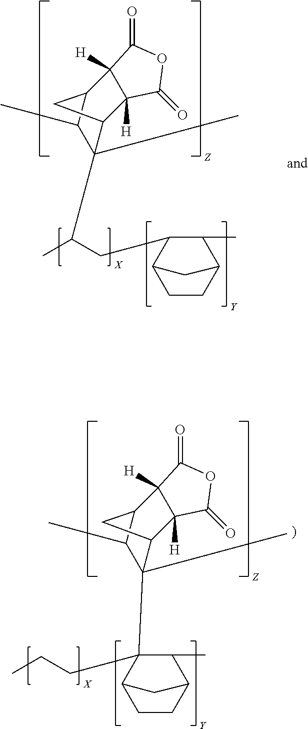

were formed. Differently from the above example 1, the benzoperoxide of 0.087 g was replaced by benzoperoxide of 0.086 g, and the maleic anhydride of 0.351 g was replaced by norbornene endo dicarboxylic anhydride of 0.583 g. A grafting ratio of the norbornene endo dicarboxylic anhydride is of 3%.

A polyamic acid solution was formed, using same steps of the above example 1.

A resin composition was formed, which comprised resin having chemical structures of

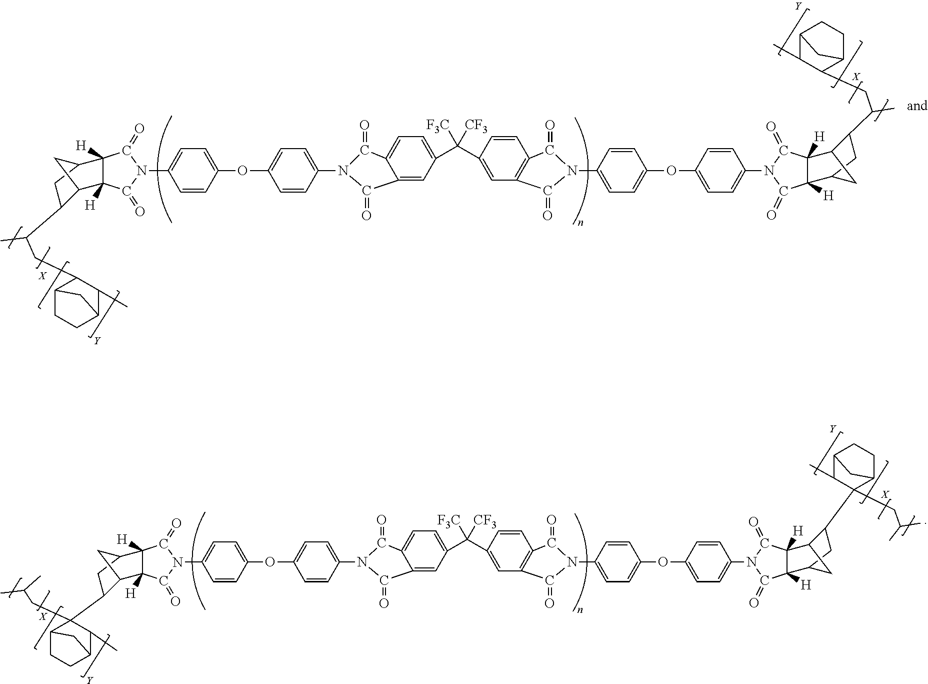

Differently from the above example 1, the modified cyclic olefin copolymers of 0.44 g were replaced by modified cyclic olefin copolymers of 0.67 g, and the methylbenzene of 9.43 mL was replaced by methylbenzene of 9.03 mL. The modified cyclic olefin copolymers and the polyamic acid solution were in a ratio of 2:3 by weight.

A film 20 was formed by the resin composition, using same steps of the above example 1.

### Comparative Example

A polyamic acid solution was formed, using same steps of the above example 1.

The polyamic acid solution was coated on a surface of a glass substrate. Then, a polyimide film was formed by the polyamic acid solution, using same steps of the above example 1.

Dielectric constant Dₖ, dielectric loss D_{f}, surface impedance, water absorption, and glass transition temperature Tg of the films 20 of the above examples 1 and 2, and the polyimide film of the above comparative example were tested. The test results are shown in table 1.

TABLE 1

Product

| | | | comparative |
|---|---|---|---|
| property | example 1 | Example 2 | example |
| Dₖ(10 GHz) | 3.00 | 2.86 | 3.15 |
| D_{f}(10 GHz) | 0.0136 | 0.011 | 0.0155 |
| surface | 9.31 × 10¹⁵ | 1.53 × 10¹⁶ | 3.74 × 10¹⁴ |
| impedance (Ω) | | | |
| water absorption | 1.62 | 1.35 | 1.93 |
| (%) | | | |
| Tg (degrees | 309 | 310 | 299 |
| Celsius) | | | |

Table 1 illustrates that the films 20 of the above examples 1 and 2 have a lower dielectric constant Dₖ, a lower dielectric loss D_{f}, a lower water absorption, a higher surface impedance, and a higher glass transition temperature Tg, compared to the polyimide film of the above comparative example.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A method for making a resin composition comprising:
providing modified cyclic olefin copolymers formed by modifying cyclic olefin copolymers by at least one of maleic anhydride and norbornene endo dicarboxylic anhydride, the modified cyclic olefin copolymers formed by the maleic anhydride having at least one chemical structure of 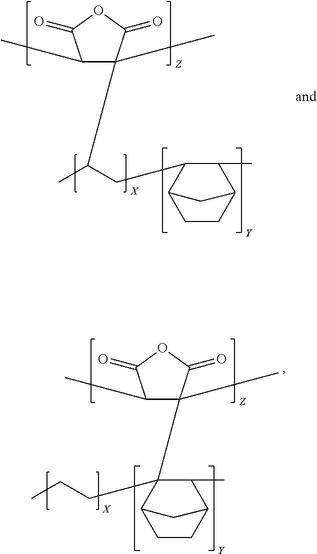
the modified cyclic olefin copolymers formed by the norbornene endo dicarboxylic anhydride having at least one chemical structure of 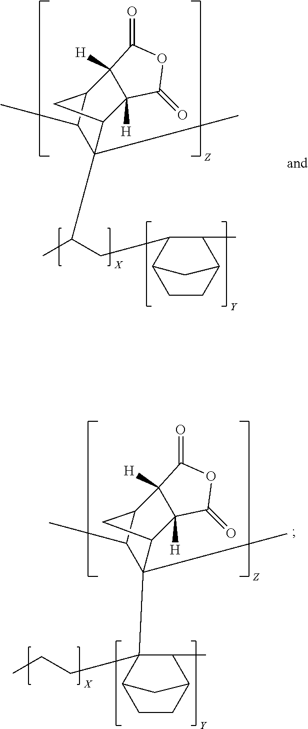
providing a polyamic acid solution, the polyamic acid solution comprising polyamic acid having a chemical structure of 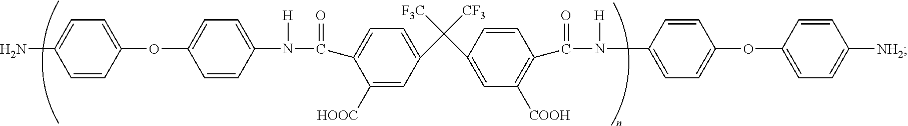
and
dissolving the modified cyclic olefin copolymers in a solvent, and adding the polyamic acid solution into the modified cyclic olefin copolymers to cause the modified cyclic olefin copolymers and polyamic acid to polymerize, thereby forming the resin composition.

2. The method of claim 1, further comprising:
removing suspensions after the modified cyclic olefin copolymers and the polyamic acid polymerize.

3. The method of claim 1, wherein “providing modified cyclic olefin copolymers” further comprises:
dissolving metallocene cyclic olefin copolymers in methylbenzene, the metallocene cyclic olefin copolymers having a chemical structure of 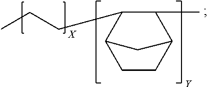
adding benzoperoxide and at least one of the maleic anhydride and the norbornene endo dicarboxylic anhydride into the metallocene cyclic olefin copolymers under a nitrogen atmosphere to form a mixture;
heating the mixture to 120 degrees Celsius and cooling the mixture to a preset temperature, to cause the mixture to undergo a reflux reaction at the preset temperature for 6 hours;
adding a methanol into the mixture after the reflux reaction to terminate the reflux reaction; and
separating precipitations from the mixture and drying the precipitations, thereby forming the modified cyclic olefin copolymers.

4. The method of claim 3, wherein a grafting ratio of the at least one of the maleic anhydride and the norbornene endo dicarboxylic anhydride is of 3%.

5. The method of claim 1, wherein “providing a polyamic acid solution” further comprises:
dissolving 4,4′-diaminodiphenyl ether in N-methylpyrrolidone;
adding 4,4′-(hexafluoroisopropylidene) diphthalic anhydride into the 4,4′-diaminodiphenyl ether, and stirring the 4,4′-(hexafluoroisopropylidene) diphthalic anhydride and the 4,4′-diaminodiphenyl ether to cause the 4,4′-(hexafluoroisopropylidene) diphthalic anhydride and the 4,4′-diaminodiphenyl ether to undergo an in-situ polymerization, thereby forming the polyamic acid solution.

6. The method of claim 5, wherein the 4,4′-(hexafluoroisopropylidene) diphthalic anhydride and the 4,4′-diaminodiphenyl ether undergo the in-situ polymerization for 24 hours.

7. The method of claim 1, wherein the modified cyclic olefin copolymers and the polyamic acid solution are in a ratio of 1:9 to 2:3 by weight.

8. The method of claim 1, wherein the modified cyclic olefin copolymers and the polyamic acid polymerize at normal temperature for 24 hours.

9. The method of claim 1, wherein the solvent is methylbenzene.

10. A resin composition comprising:
resins having a chemical structure selected from a group consisting of 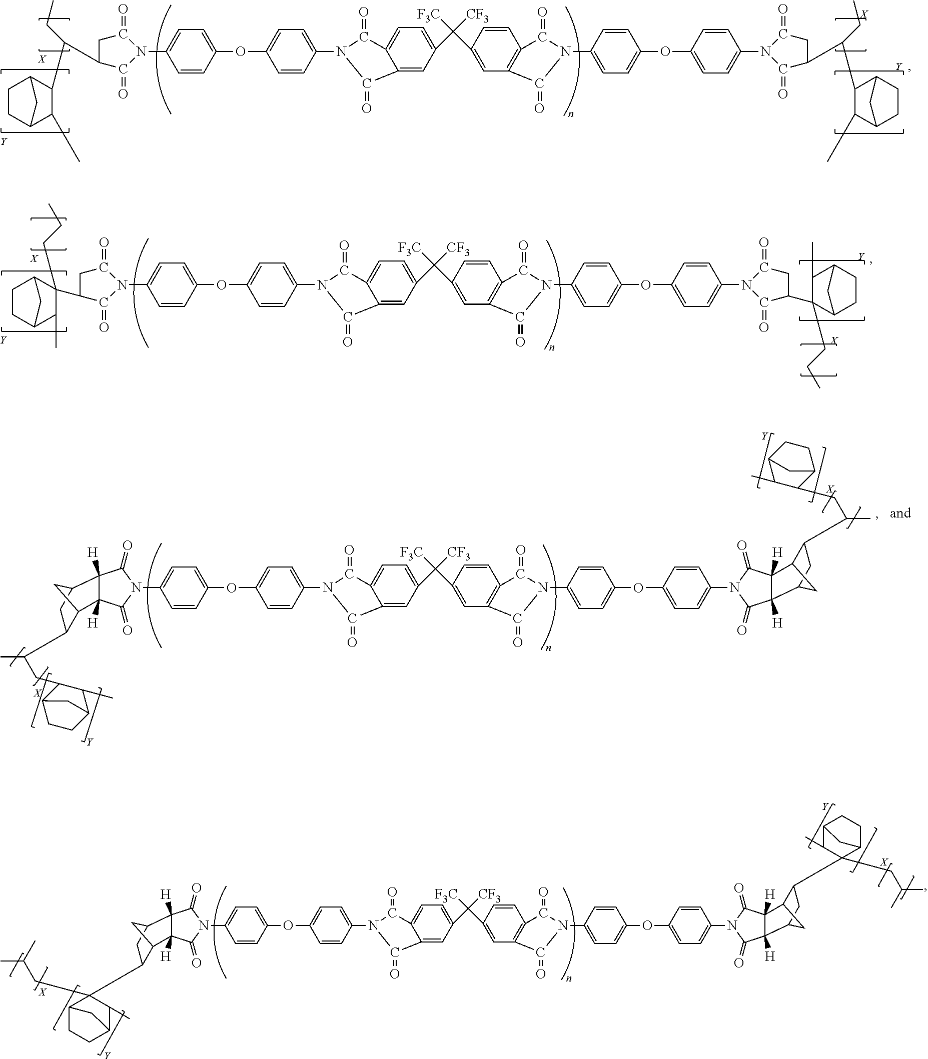
or any combination thereof.

11. A method for making a film comprising:
providing a resin composition, the resin composition comprising resins having a chemical structure selected from a group consisting of 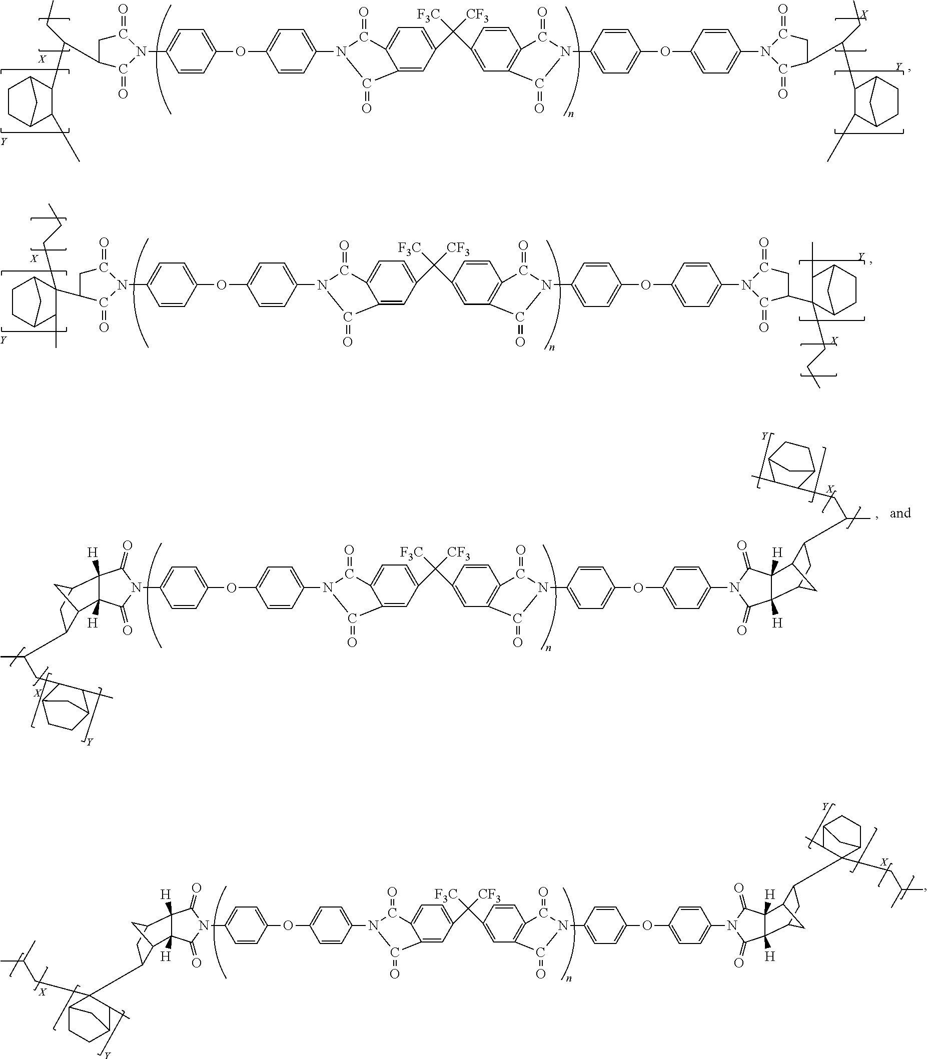
or any combination thereof;
coating the resin composition on a surface of a glass substrate, and heating the resin composition to cause the resins of the resin composition to undergo a ring-closure reaction; and
drying the resin composition after the ring-closure reaction and separating the dried resin composition from the glass substrate, thereby forming the film.

12. The method of claim 11, wherein “heating the resin composition” further comprising:
heating the resin composition from normal temperature to 100 degrees Celsius and remaining the resin composition at 100 degrees Celsius for one hour;
heating the resin composition from 100 degrees Celsius to 150 degrees Celsius and remaining the resin composition at 150 degrees Celsius for one hour;
heating the resin composition from 150 degrees Celsius to 200 degrees Celsius and remaining the resin composition at 200 degrees Celsius for one hour;
heating the resin composition from 200 degrees Celsius to 250 degrees Celsius and remaining the resin composition at 250 degrees Celsius for one hour; and
heating the resin composition from 250 degrees Celsius to 300 degrees Celsius and remaining the resin composition at 300 degrees Celsius for two hours.

13. A circuit board comprising;
at least one substrate; and
a film formed on at least one surface of each substrate, the film formed by heating a resin composition to cause resins of the resin composition to undergo a ring-closure reaction;
wherein the resins have a chemical structure selected from a group consisting of 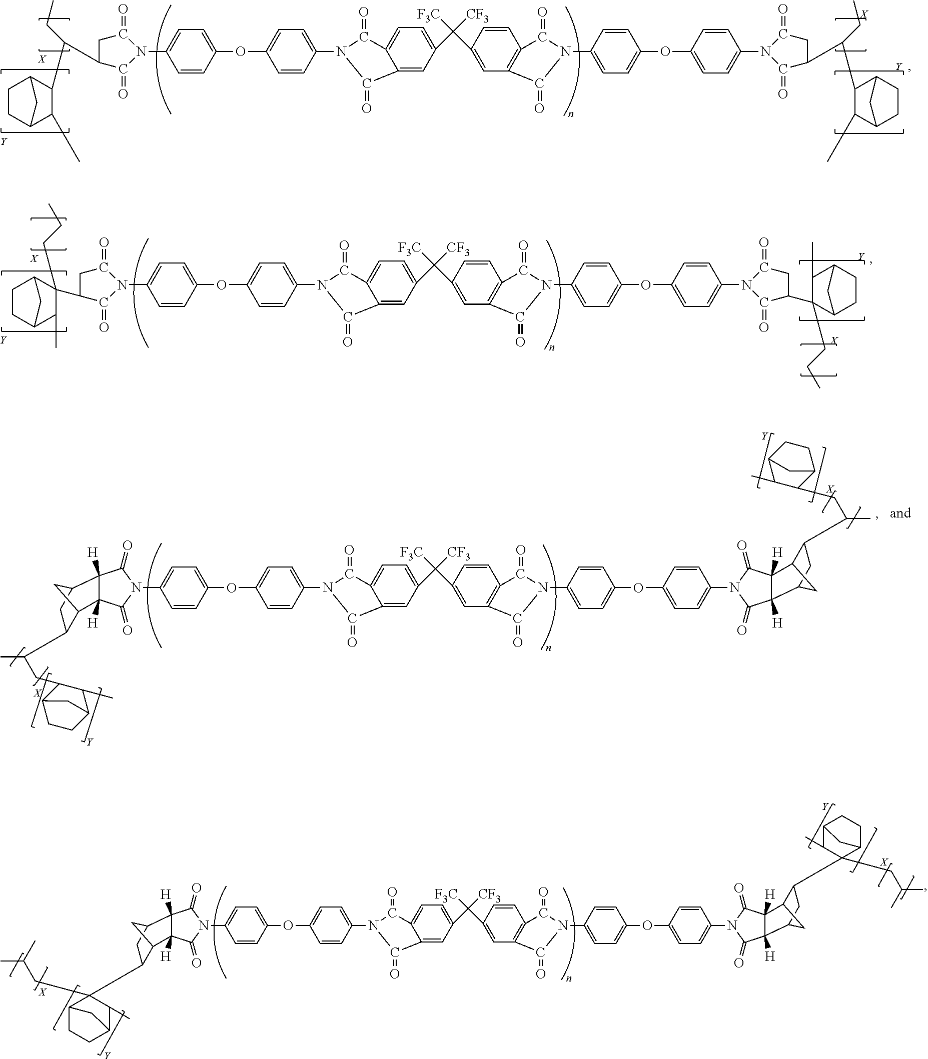
or any combination thereof.
